(19) United States
(12) Patent Application Publication
(10) Pub. No.: US 2015/0263040 A1
(43) Pub. Date: Sep. 17, 2015

(54) Embedded Memory Device With Silicon-On-Insulator Substrate, And Method Of Making Same

(71) Applicant: Silicon Storage Technology, Inc., San Jose, CA (US)

(72) Inventors: Chien-Sheng Su, Saratoga, CA (US); Hieu Van Tran, San Jose, CA (US); Mandana Tadayoni, Cupertino, CA (US); Nhan Do, Saratoga, CA (US)

(73) Assignee: Silicon Storage Technology, Inc., San Jose, CA (US)

(21) Appl. No.: 14/216,553

(22) Filed: Mar. 17, 2014

(51) Int. Cl. H01L 27/12; H01L 29/66; H01L 27/115; H01L 29/788; H01L 29/78

(52) U.S. Cl. CPC H01L 27/1203; H01L 29/788; H01L 29/7841; H01L 27/11521; H01L 29/66825

(57) ABSTRACT

A semiconductor device having a silicon substrate with a first area including a buried insulation layer with silicon over and under the insulation layer and a second area in which the substrate lacks buried insulation disposed under any silicon. Logic devices are formed in the first area having spaced apart source and drain regions formed in the silicon that is over the insulation layer, and a conductive gate formed over and insulated from a portion of the silicon that is over the insulation layer and between the source and drain regions. Memory cells are formed in the second area that include spaced apart second source and second drain regions formed in the substrate and defining a channel region therebetween, a floating gate disposed over and insulated from a first portion of the channel region, and a select gate disposed over and insulated from a second portion of the channel region.

### FIELD OF THE INVENTION

The present invention relates to embedded non-volatile memory devices.

### BACKGROUND OF THE INVENTION

Non-volatile memory devices formed on bulk silicon semiconductor substrates are well known. For example, U.S. Pat. Nos. 6,747310, 7,868,375 and 7,927,994 disclose memory cells with four gates (floating gate, control gate, select gate and erase gate) formed on a bulk semiconductor substrate. Source and drain regions are formed as diffusion implant regions into the substrate, defining a channel region therebetween in the substrate. The floating gate is disposed over and controls a first portion of the channel region, the select gate is disposed over and controls a second portion of the channel region, the control gate is disposed over the floating gate, and the erase gate is disposed over the source region. Bulk substrates are ideal for these type of memory devices because deep diffusions into the substrate can be used for forming the source and drain region junctions. These three patents are incorporated herein by reference for all purposes.

Silicon on insulator (SOI) devices are well known in the art of microelectronics. SOI devices differ from bulk silicon substrate devices in that the substrate is layered with an embedded insulating layer under the silicon surface (i.e. silicon-insulator-silicon) instead of being solid silicon. With SOI devices, the silicon junctions are formed in a thin silicon layer disposed over the electrical insulator that is embedded in the silicon substrate. The insulator is typically silicon dioxide (oxide). This substrate configuration reduces parasitic device capacitance, thereby improving performance. SOI substrates can be manufactured by SIMOX (separation by implantation of oxygen using an oxygen ion beam implantation—see U.S. Pat. Nos. 5,888,297 and 5,061,642), wafer bonding (bonding oxidized silicon with a second substrate and removing most of the second substrate—see U.S. Pat. No. 4,771,016), or seeding (topmost silicon layer grown directly on the insulator—see U.S. Pat. No. 5,417,180). These four patents are incorporated herein by reference for all purposes.

It is known to form core logic devices such as high voltage, input/output and/or analog devices on the same substrate as non-volatile memory devices (i.e. typically referred to as embedded memory devices). As device geometries continue to shrink, these core logic devices could benefit greatly from the advantages of SOI substrates. However, the non-volatile memory devices are not conducive to SOI substrates. There is a need to combine the advantages of core logic devices formed on an SOI substrate with memory devices formed on bulk substrates.

### BRIEF SUMMARY OF THE INVENTION

A semiconductor device includes a silicon substrate having a first area in which the substrate includes a buried insulation layer with silicon over and under the insulation layer, and having a second area in which the substrate lacks buried insulation disposed under any silicon. Logic devices are formed in the first area, wherein each of the logic devices includes spaced apart source and drain regions formed in the silicon that is over the insulation layer, and a conductive gate formed over and insulated from a portion of the silicon that is over the insulation layer and between the source and drain regions. Memory cells are formed in the second area, wherein each of the memory cells includes spaced apart second source and second drain regions formed in the substrate and defining a channel region therebetween, a floating gate disposed over and insulated from a first portion of the channel region, and a select gate disposed over and insulated from a second portion of the channel region.

A method of forming a semiconductor device includes providing a silicon substrate that includes a buried insulation layer with silicon over and under the insulation layer, removing the buried insulation layer from a second area of the substrate while maintaining the buried insulation layer in a first area of the substrate, forming logic devices in the first area of the substrate wherein each of the logic devices includes spaced apart source and drain regions formed in the silicon that is over the insulation layer and a conductive gate formed over and insulated from a portion of the silicon that is over the insulation layer and between the source and drain regions and forming memory cells in the second area of the substrate wherein each of the memory cells includes spaced apart second source and second drain regions formed in the substrate and defining a channel region therebetween, a floating gate formed over and insulated from a first portion of the channel region, and a select gate formed over and insulated from a second portion of the channel region.

Other objects and features of the present invention will become apparent by a review of the specification, claims and appended figures.

### BRIEF DESCRIPTION OF THE DRAWINGS

FIGS. 1-9 are side cross sectional views illustrating in sequence the processing steps performed to manufacture the embedded memory device of the present invention.

FIG. 10A is a side cross sectional view illustrating the next processing steps processing steps performed to manufacture the embedded memory device of the present invention.

FIG. 10B is a side cross sectional view orthogonal to that of FIG. 10A for the memory area of the structure.

FIGS. 11-14 are side cross sectional views illustrating in sequence the next processing steps performed to manufacture the embedded memory device of the present invention.

FIG. 15 is a side cross sectional view orthogonal to that of FIG. 14 for the core logic area and the memory area of the structure.

### DETAILED DESCRIPTION OF THE INVENTION

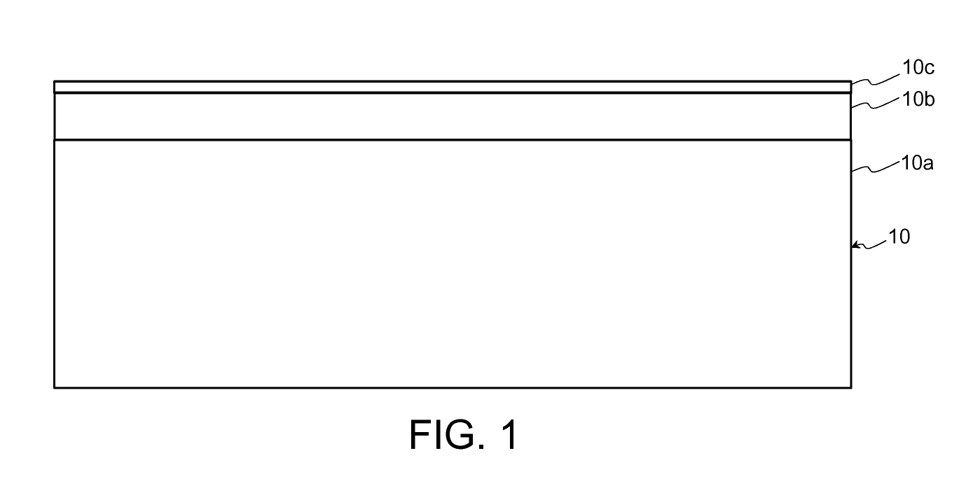

The present invention is an embedded memory device with non-volatile memory cells formed alongside core logic devices on an SOI substrate. The embedded insulator is removed from the memory area of the SOI substrate in which the non-volatile memory is formed. The process of forming embedded memory devices on an SOI substrate begins by providing an SOI substrate 10, as illustrated in FIG. 1. The SOI substrate includes three portions: silicon 10a, a layer of insulating material 10b (e.g. oxide) over the silicon 10a, and a thin layer of silicon 10c over the insulator layer 10b. Forming SOI substrates is well known in the art as described above and in the U.S. patents identified above, and therefore is not further described herein.

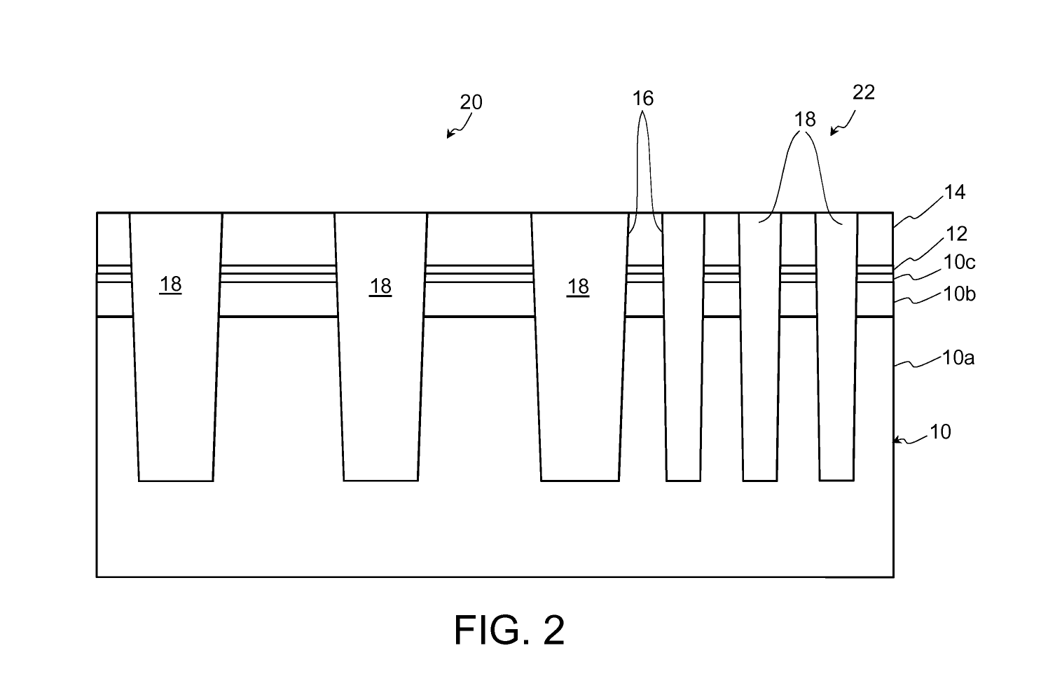

A first layer of insulation material 12, such as silicon dioxide (oxide), is formed on the silicon 10c. Layer 12 can be formed, for example, by oxidation or by deposition (e.g. chemical vapor deposition CVD). A second layer of insulation material 14, such as silicon nitride (nitride) is formed on layer 12. A photolithography process is performed which includes forming a photo-resist material on nitride 14, followed by selectively exposing the photo-resist material to light using an optical mask, which is following by selectively removing portions of the photo-resist material to expose portions of nitride layer 14. Photolithography is well known in the art. A series of etches are then performed in those exposed areas to remove nitride 14, oxide 12, silicon 10c, oxide 10b and silicon 10a (i.e. nitride etch to expose oxide 12, oxide etch to expose silicon 10c, silicon etch to expose oxide 10b, oxide etch to expose silicon 10a, and a silicon etch) to form trenches 16 that extend down through layers 14, 12, 10c, 10b and into silicon 10a. After the photo-resist material is removed, the trenches 16 are filled with an insulating material 18 (e.g. oxide) by an oxide deposition and oxide etch (e.g. chemical mechanical polish, CMP, using nitride 14 as an etch stop), resulting in the structure shown in FIG. 2. Insulating material 18 serves as isolation regions for both the core logic area 20 and memory area 22 of the substrate 10.

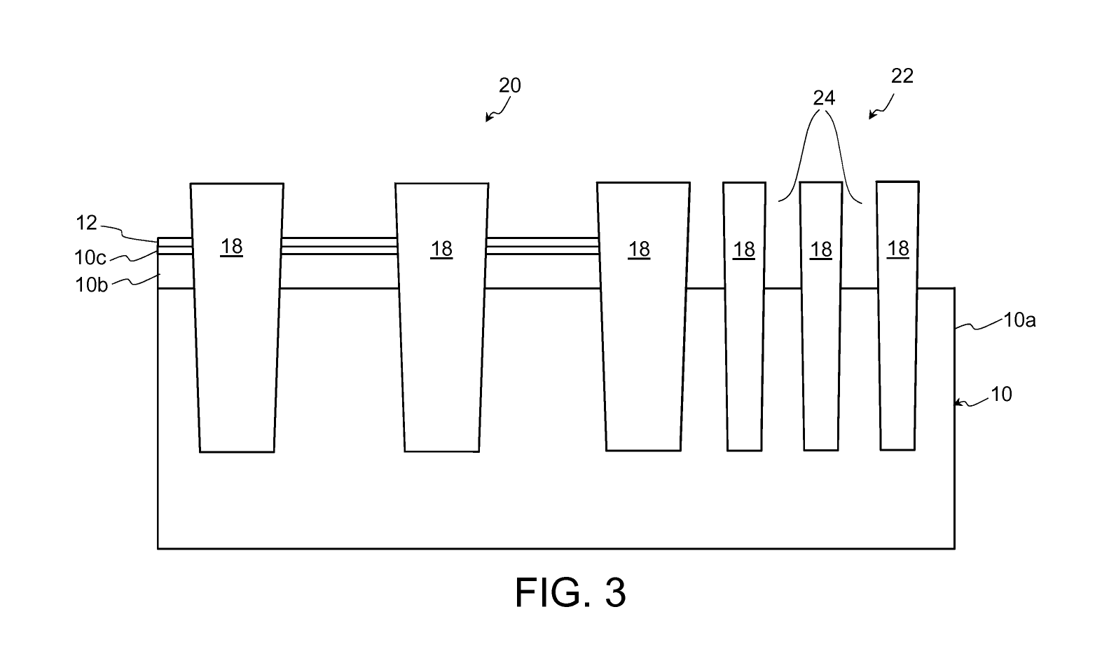

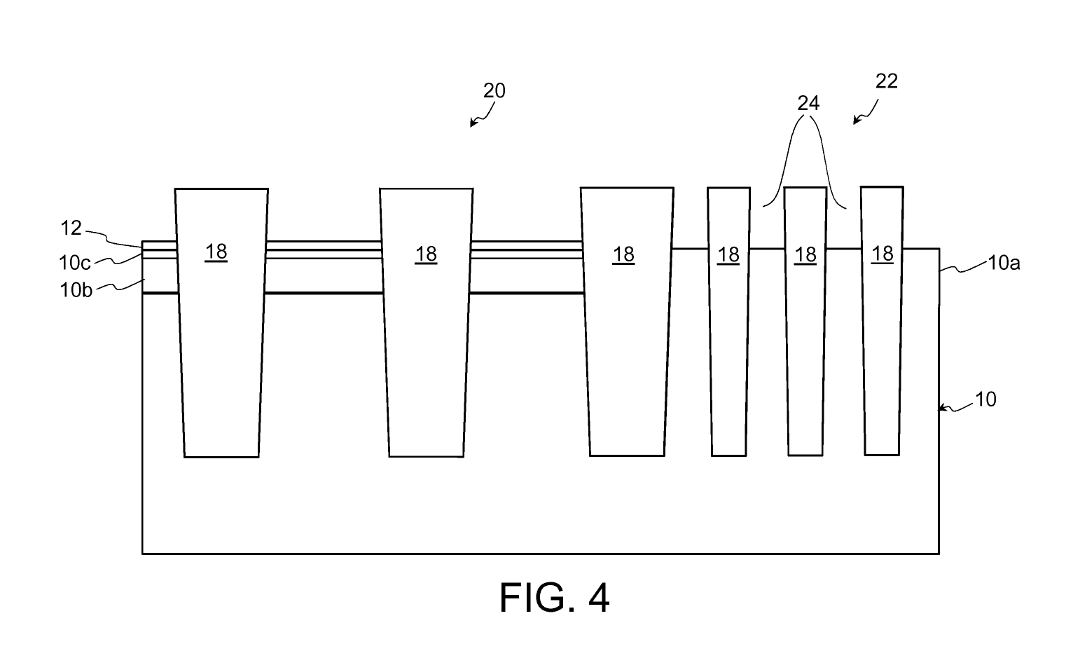

A nitride etch is next performed to remove nitride 14. A photolithography process is performed to form photo-resist over the structure, followed by a masking step in which the photo resist is removed from the memory area 22 but not the core logic area 20 of the structure. A series of etches are performed to remove the oxide 12, silicon 10c and oxide 10b in the exposed memory area 22 (i.e. form trenches 24 between oxide 18 that extend down to silicon 10a). The photo-resist in then removed, resulting in the structure of FIG. 3. A selective epitaxial silicon growth process is then performed (i.e. on silicon 10a) to form silicon in trenches 24 in the memory area 22 up to the level of the silicon layer 10c in the core logic area 20, as illustrated in FIG. 4. Essentially, this silicon growth process extends silicon 10a up to the level of silicon layer 10c. Thus, the embedded oxide 10b of SOI substrate 10 is effectively removed from the memory area 22 while being maintained in the core logic area 20.

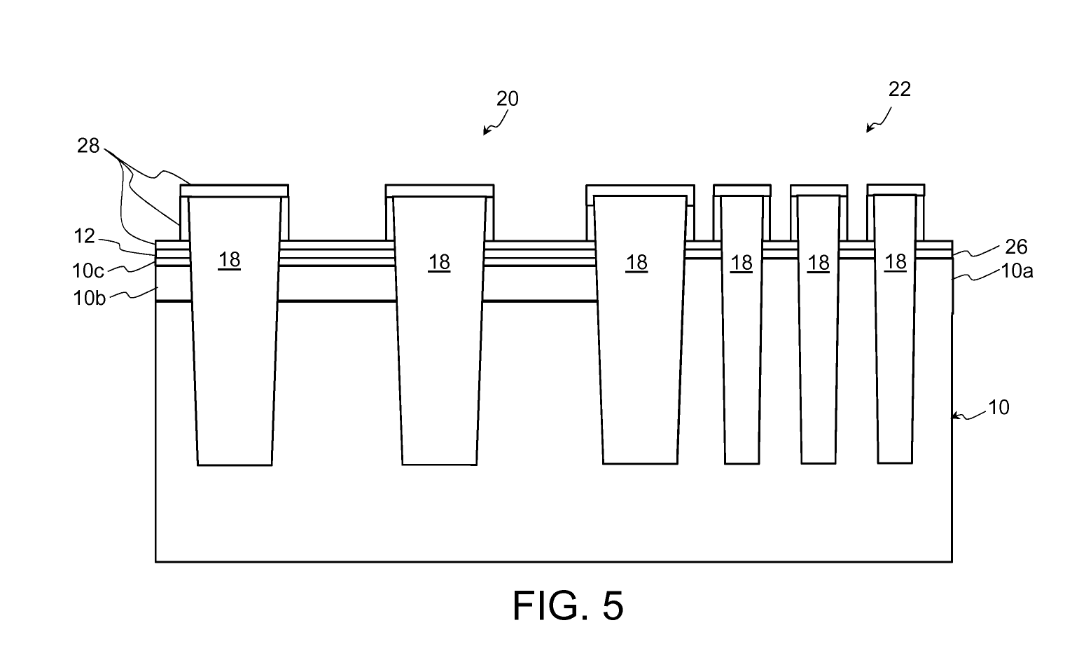

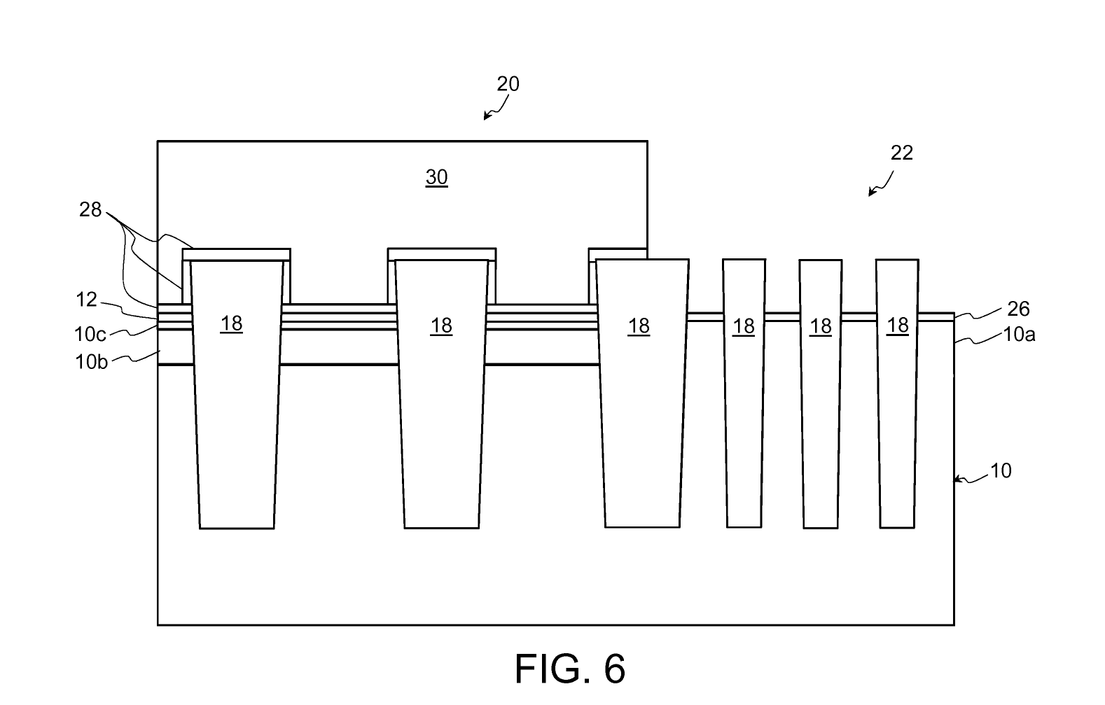

From this point forward, core logic devices can be formed on silicon layer 10c in the core logic area 20 and memory devices can be formed on silicon 10a in the memory area 22. Described next are steps forming exemplary core logic and memory devices starting with the structure in FIG. 4. An oxide deposition or oxidation step is used to form oxide layer 26 on substrate 10a. An insulation layer 28 such as nitride is formed over the structure (i.e. on oxides 12, 18 and 26), as illustrated in FIG. 5. Photo-resist 30 is then deposited over the entire structure, following by a photolithography process that removes the photo-resist 30 in the memory area 22 while retaining it in the core logic area 20. A nitride etch (e.g. isotropic nitride etch) is then used to remove the exposed nitride 28 in the memory area 22. The resulting structure is shown in FIG. 6.

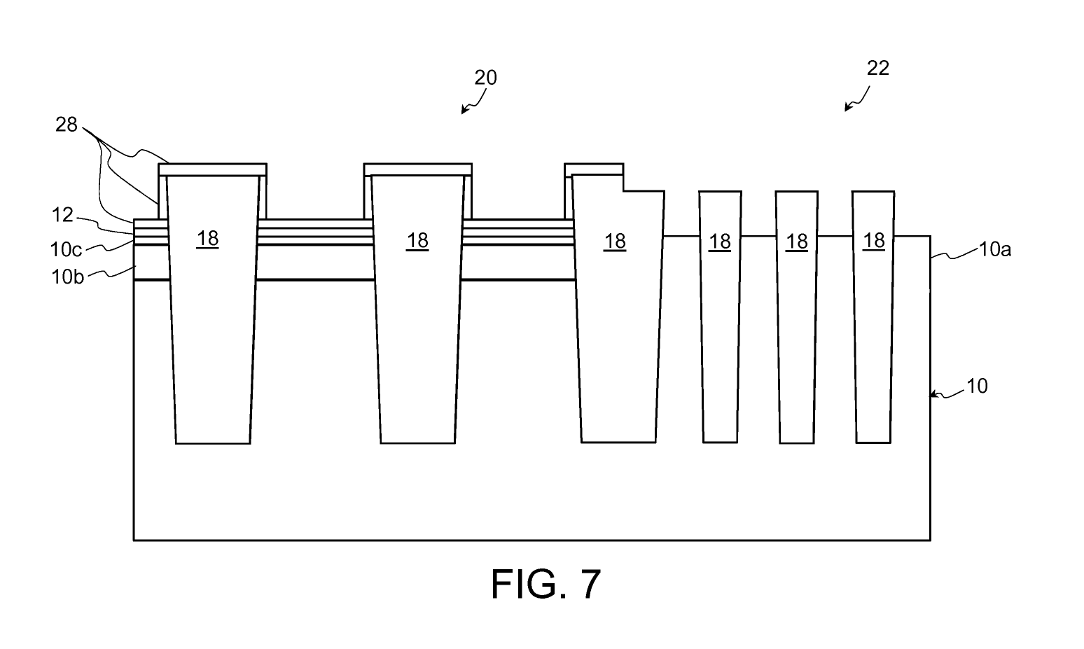

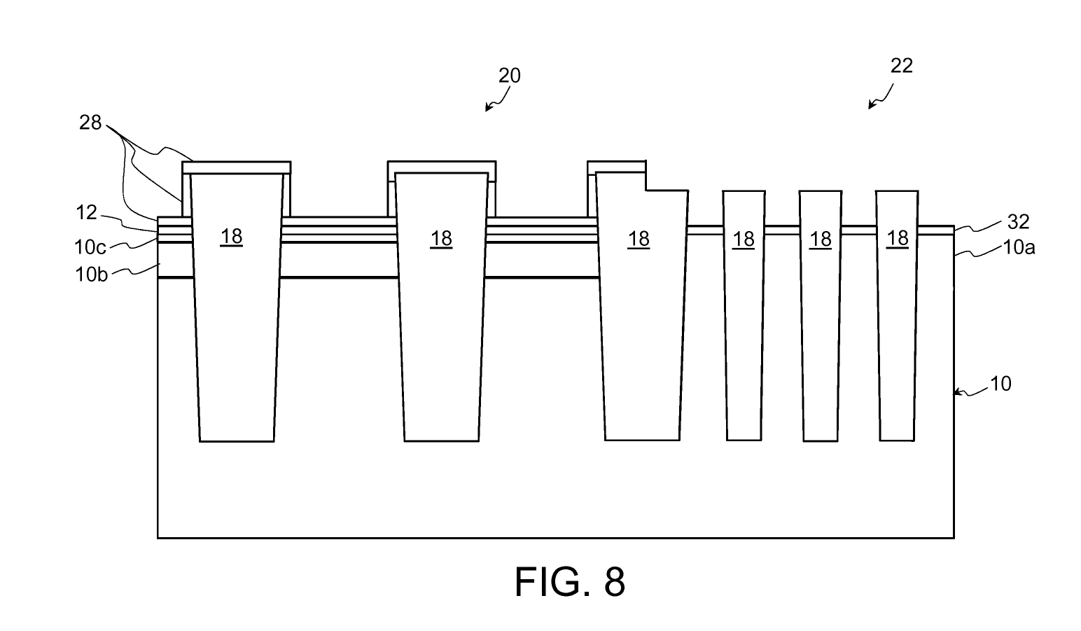

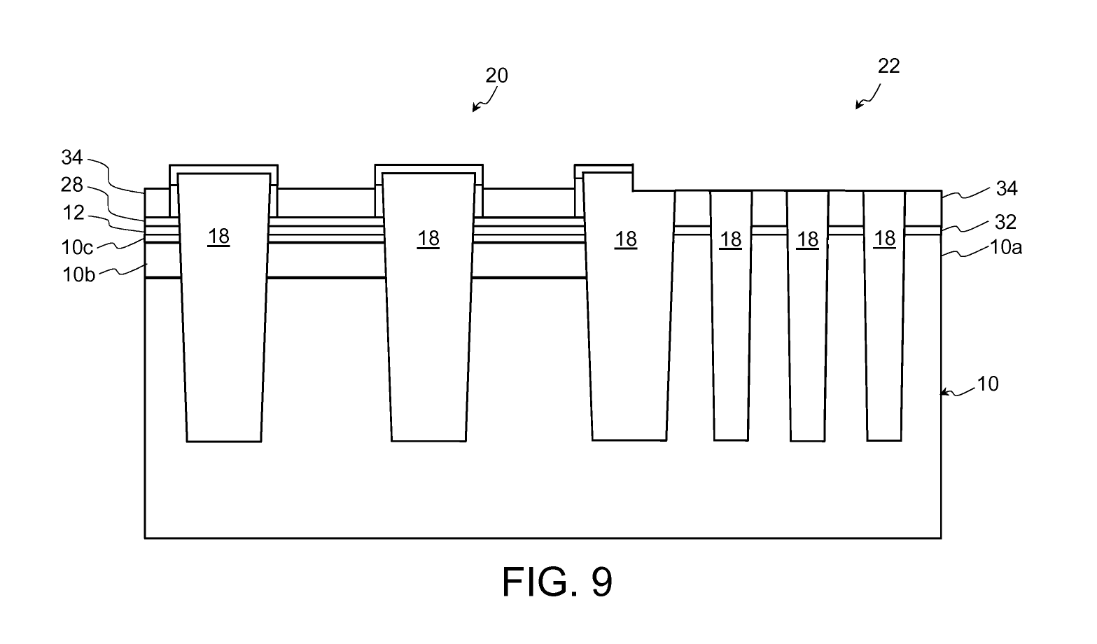

After photo-resist 30 is removed, an oxide etch is used to remove oxide 26 from the memory area 22, as shown in FIG. 7. The oxide etch also reduces the height of oxide 18 in the memory area 22. An oxide formation step (e.g. oxidation) is then used to form oxide layer 32 on substrate 10a in the memory area 22 (which will be the oxide on which the floating gate will be formed), as shown in FIG. 8. Polysilicon is formed over the structure, followed by a poly removal (e.g. CMP), leaving poly layer 34 in both the core logic area 20 and the memory area 22. Preferably, but not necessarily, the top surfaces of poly 34 and oxide 18 in the memory area 22 are co-planar (i.e. use oxide 18 as the etch stop for the poly removal). The resulting structure is shown in FIG. 9.

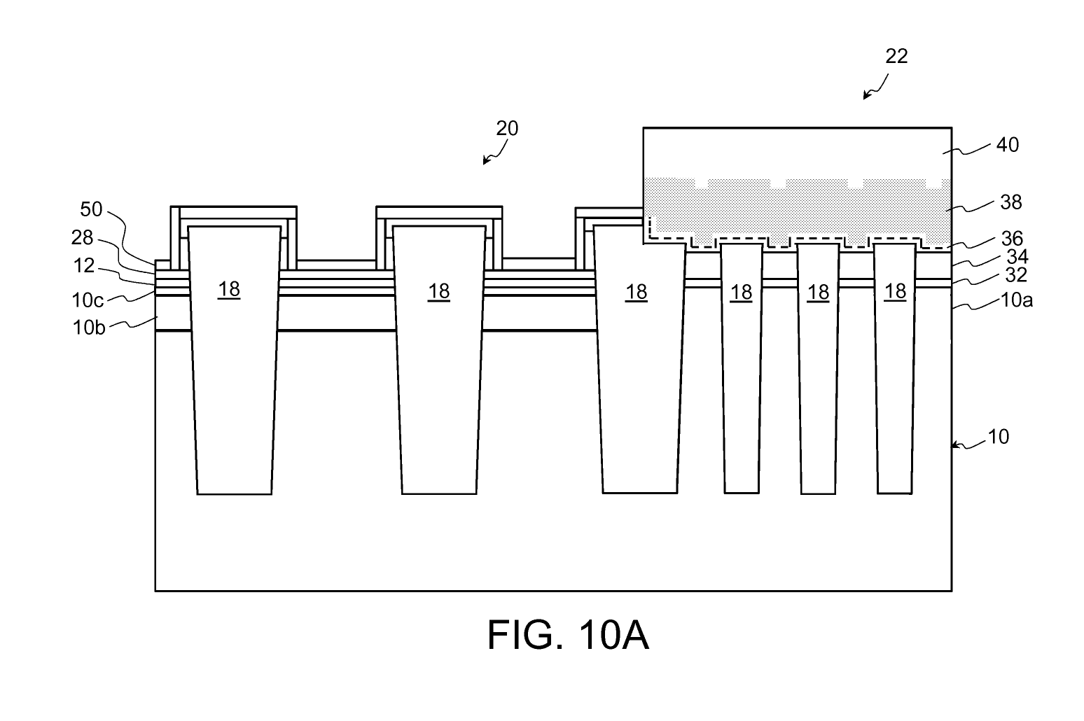

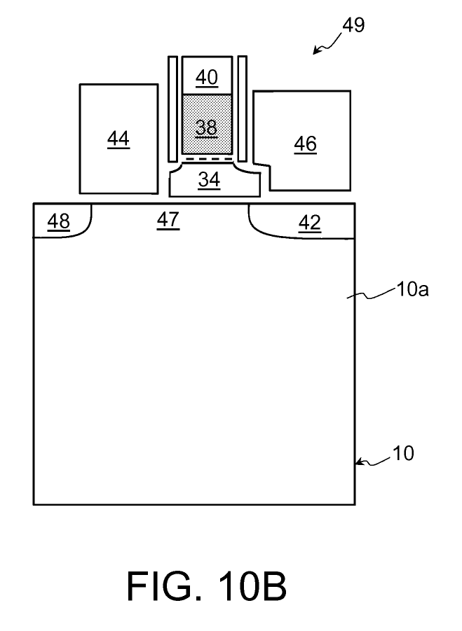

A series of processing steps are next performed to complete the memory cell formation in the memory area 22, which are well known in the art. Specifically, poly 34 forms the floating gate. An insulating a layer 36 (e.g. oxide) is formed over poly 34. A conductive control gate 38 is formed on oxide 36, and a hard mask material 40 (e.g. a composite layer of nitride, oxide and nitride) is formed over the control gate 38. A source diffusion 42 is formed in substrate 10a to one side of the floating gate. A select gate 44 is formed over and insulated from the substrate 10a on the other side of the floating gate 34. An erase gate 46 is formed over the source region 42. A drain diffusion 48 is formed in substrate 10a adjacent the select gate 44. The source and drain regions 42/48 define a channel region 47 therebetween, with the floating gate 34 disposed over and controlling a first portion of the channel region 47 and the select gate 44 disposed over and controlling a second portion of the channel region 47. The formation of these memory cells is known in the art (see U.S. Pat. Nos. 6,747310, 7,868,375 and 7,927,994 incorporated herein by reference above) and not further described herein. The resulting structure is shown in FIGS. 10A and 10B (FIG. 10B is a view orthogonal to that of FIG. 10A of a memory cell 49 formed in the memory area 22). The memory cell 49 has a floating gate 34, control gate 38, source region 42, select gate 44, erase gate 46, and drain region 48). The memory cell processing steps end up removing poly 34 from the core logic area 20, and add an insulation layer 50 (e.g. high temperature oxide layer—HTO) over nitride layer 28, as illustrated in FIG. 10A.

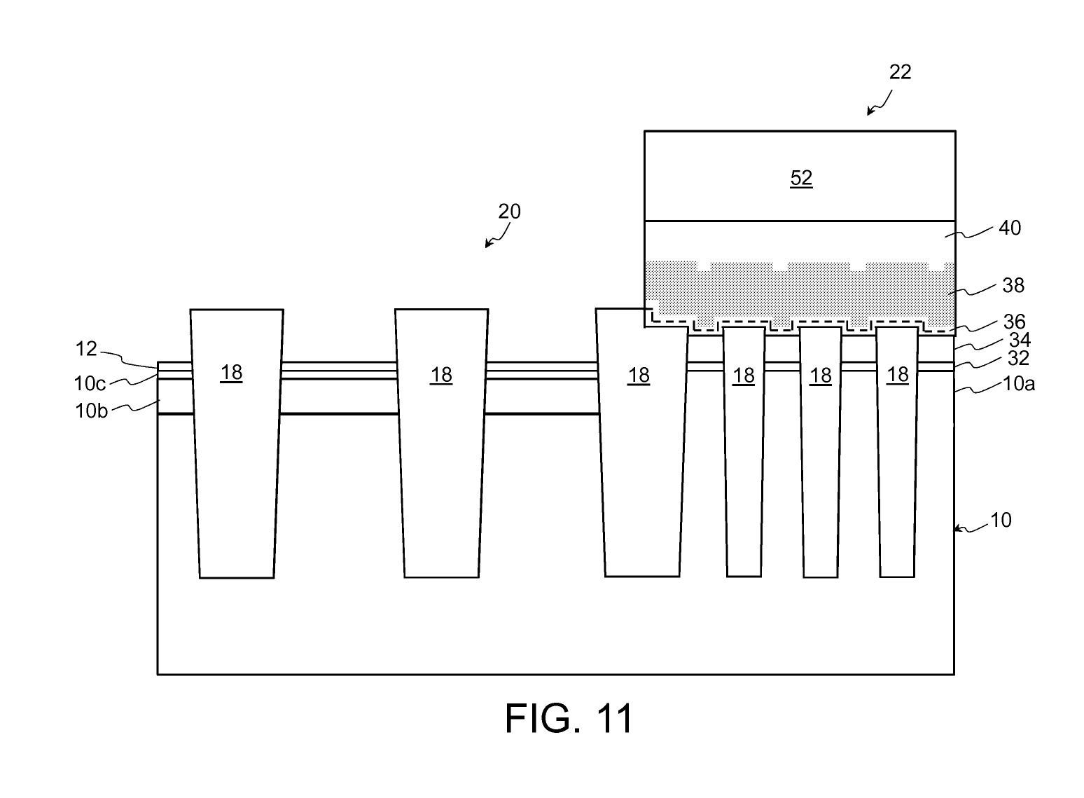

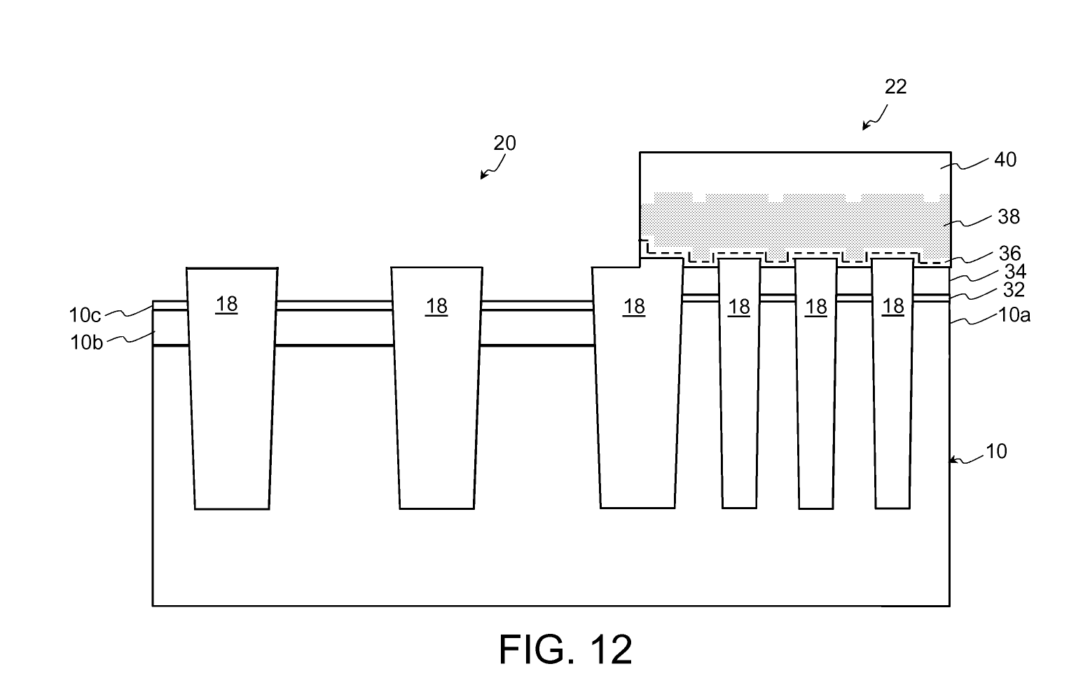

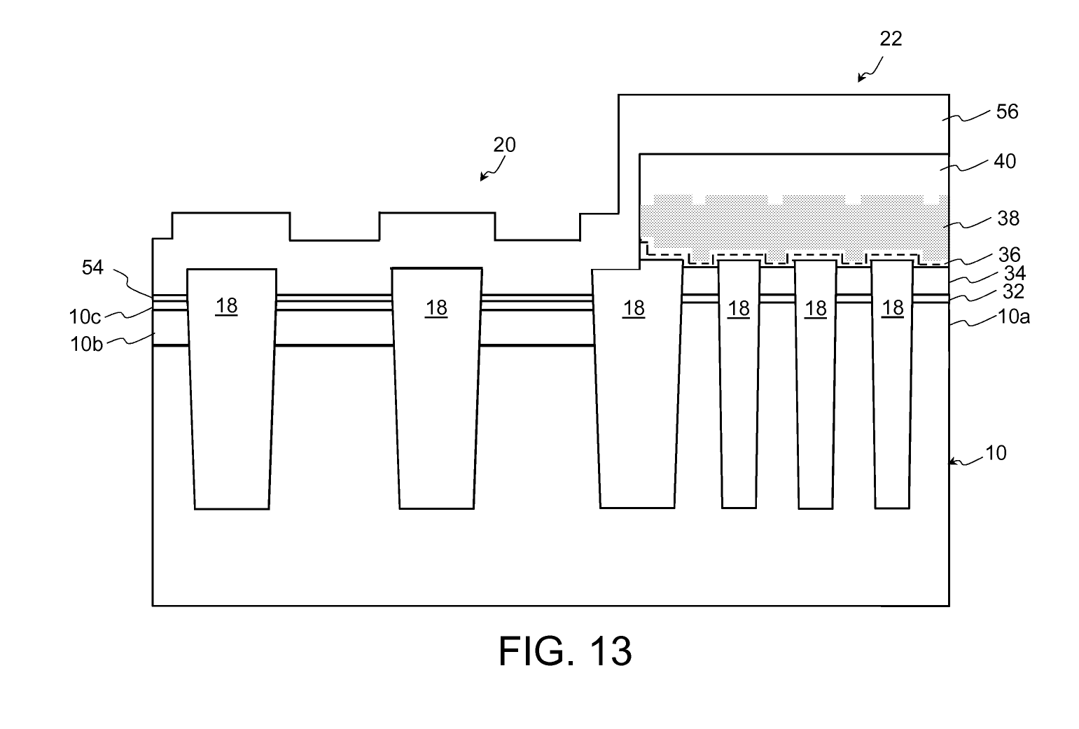

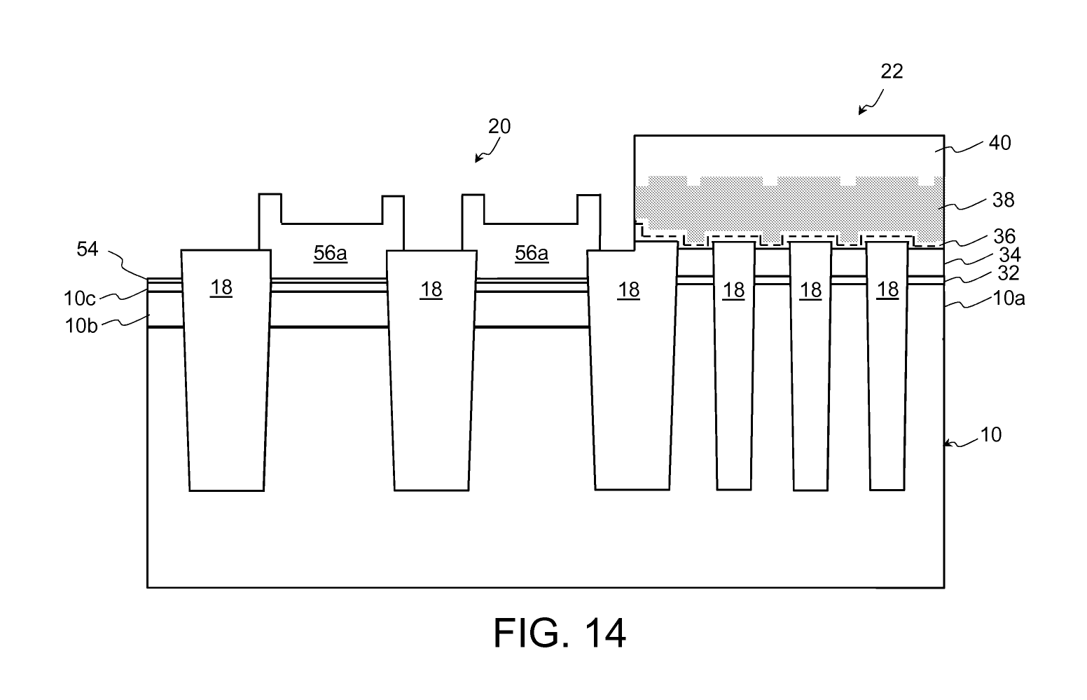

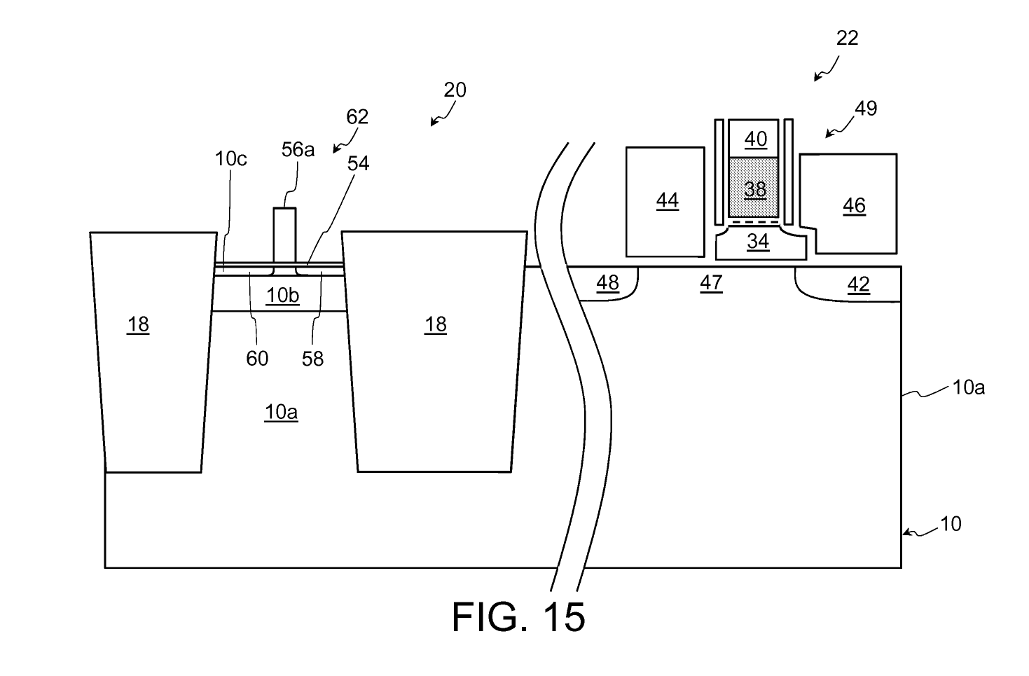

Photo-resist 52 is formed over the structure, and removed from just the core logic area 20 using a photolithography process. Oxide and nitride etches are performed to remove oxide layer 50 and nitride layer 28 from the core logic area 20, as illustrated in FIG. 11. An oxide etch (e.g. dry and wet) is performed to remove oxide layer 12 from core logic area 20 (which also removes to the tops of oxide 18). The photo-resist 52 is then removed, resulting in the structure illustrated in FIG. 12. A thin insulation layer is formed on the exposed silicon layer 10c (e.g. oxide via oxidation), which will be the gate oxide for the core logic devices. A polysilicon layer 56 is then formed on the structure as illustrated in FIG. 13. A photolithography process is used to form blocks of photoresist on poly layer 56 (which are disposed over oxide 18), followed by a poly etch process that leaves poly blocks 56a in the core logic area 20, as illustrated in FIG. 14. Poly blocks 56a form logic gates for the core logic devices in area 20. Suitable source and drain diffusion regions 58 and 60 are formed in the thin silicon layer 10c to complete the logic devices 62, as illustrated in FIG. 15 (which is a view orthogonal to that of FIG. 14).

The above described manufacturing process forms memory cells 49 and core logic devices on the same SOI substrate, where the embedded insulator layer 10b of the SOI substrate 10 is effectively removed from the memory area 22. This configuration allows the source and drain regions 42/48 of the memory cells to extend deeper into the substrate than the source and drain regions 58/60 in the core logic area 20 (i.e. source/drain 42/48 can extend deeper than the thickness of silicon layer 10c and thus deeper than the top surface of insulation layer 10b in the core logic area, and even possibly deeper than the bottom surface of insulation layer 10b in the core logic area).

It is to be understood that the present invention is not limited to the embodiment(s) described above and illustrated herein, but encompasses any and all variations falling within the scope of the appended claims. For example, references to the present invention herein are not intended to limit the scope of any claim or claim term, but instead merely make reference to one or more features that may be covered by one or more of the claims. Materials, processes and numerical examples described above are exemplary only, and should not be deemed to limit the claims. Further, as is apparent from the claims and specification, not all method steps need be performed in the exact order illustrated or claimed, but rather in any order that allows the proper formation of the memory cell area and the core logic area of the present invention. Memory cell 49 can include additional or fewer gates than described above and illustrated in the figures. Lastly, single layers of material could be formed as multiple layers of such or similar materials, and vice versa.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between). For example, forming an element “over a substrate” can include forming the element directly on the substrate with no intermediate materials/elements therebetween, as well as forming the element indirectly on the substrate with one or more intermediate materials/elements therebetween.

What is claimed is:

1. A semiconductor device, comprising:
a silicon substrate having a first area in which the substrate includes a buried insulation layer with silicon over and under the insulation layer, and having a second area in which the substrate lacks buried insulation disposed under any silicon;
logic devices formed in the first area, wherein each of the logic devices includes:
spaced apart source and drain regions formed in the silicon that is over the insulation layer, and
a conductive gate formed over and insulated from a portion of the silicon that is over the insulation layer and between the source and drain regions;
memory cells formed in the second area, wherein each of the memory cells includes:
spaced apart second source and second drain regions formed in the substrate and defining a channel region therebetween,
a floating gate disposed over and insulated from a first portion of the channel region, and
a select gate disposed over and insulated from a second portion of the channel region.

2. The semiconductor device of claim 1, wherein the second source and drain regions formed in the second area extend deeper into the substrate than do the source and drain regions formed in the first area.

3. The semiconductor device of claim 2, wherein the second source and drain regions formed in the second area extend deeper into the substrate than a thickness of the silicon disposed over the buried insulation layer in the first area.

4. The semiconductor device of claim 2, wherein the second source and drain regions formed in the second area extend deeper into the substrate than a depth of a top surface of the buried insulation layer in the first area.

5. The semiconductor device of claim 2, wherein the second source and drain regions formed in the second area extend deeper into the substrate than a depth of a bottom surface of the buried insulation layer in the first area.

6. The semiconductor device of claim 1, wherein each of the memory cells further comprises:
a control gate disposed over and insulated from the floating gate; and
an erase gate disposed over and insulated from the source region.

7. The semiconductor device of claim 1, wherein the first area of the substrate further comprises:
isolation regions each formed of insulation material that extends through the silicon that is over the buried insulation layer, through the buried insulation layer, and into the silicon that is under the buried insulation layer.

8. The semiconductor device of claim 7, wherein the second area of the substrate further comprises:
second isolation regions each formed of insulation material that extends into the silicon substrate.

9. A method of forming a semiconductor device, comprising:
providing a silicon substrate that includes a buried insulation layer with silicon over and under the insulation layer;
removing the buried insulation layer from a second area of the substrate while maintaining the buried insulation layer in a first area of the substrate;
forming logic devices in the first area of the substrate, wherein each of the logic devices includes:
spaced apart source and drain regions formed in the silicon that is over the insulation layer, and
a conductive gate formed over and insulated from a portion of the silicon that is over the insulation layer and between the source and drain regions;
forming memory cells in the second area of the substrate, wherein each of the memory cells includes:
spaced apart second source and second drain regions formed in the substrate and defining a channel region therebetween,
a floating gate formed over and insulated from a first portion of the channel region, and
a select gate formed over and insulated from a second portion of the channel region.

10. The method of claim 9, wherein the removing of the buried insulation layer in the second area of the substrate includes:
removing the silicon over the buried insulation layer in the second area;
removing the buried insulation layer in the second area; and
growing silicon on the substrate where the buried insulation layer and silicon were removed.

11. The method of claim 9, wherein the second source and drain regions formed in the second area extend deeper into the substrate than do the source and drain regions formed in the first area.

12. The method of claim 11, wherein the second source and drain regions formed in the second area extend deeper into the substrate than a thickness of the silicon disposed over the buried insulation layer in the first area.

13. The method of claim 11, wherein the second source and drain regions formed in the second area extend deeper into the substrate than a depth of a top surface of the buried insulation layer in the first area.

14. The method of claim 11, wherein the second source and drain regions formed in the second area extend deeper into the substrate than a depth of a bottom surface of the buried insulation layer in the first area.

15. The method of claim 9, wherein each of the memory cells further comprises:
a control gate formed over and insulated from the floating gate; and
an erase gate formed over and insulated from the source region.

16. The method of claim 9, further comprising:
forming isolation regions in the first area each including insulation material that extends through the silicon that is over the buried insulation layer, through the buried insulation layer, and into the silicon that is under the buried insulation layer.

17. The method of claim 16, further comprising:
forming second isolation regions in the second area each including second insulation material that extends into the silicon substrate.

18. The method of claim 17, wherein the forming of the isolation regions and the forming of the second isolation regions are performed before the removing of the buried insulation layer from the second area of the substrate.

19. The method of claim 18, wherein the forming of the isolation regions in the first area comprises:
forming trenches that extend through the silicon over the buried insulation layer, through the buried insulation layer, and into the silicon under the buried insulation layer; and
filling the trenches with the insulation material.

20. The method of claim 19, wherein the forming of the second isolation regions in the second area comprises:
forming second trenches that extend into the silicon substrate; and
filling the second trenches with the second insulation material.
